(19) United States
(12) Patent Application Publication
(10) Pub. No.: US 2026/0101765 A1
(43) Pub. Date: Apr. 9, 2026

(54) SEMICONDUCTOR PACKAGE WITH STACKED SEMICONDUCTOR CHIP STRUCTURE

(71) Applicant: SAMSUNG ELECTRONICS CO., LTD., Suwon-si (KR)

(72) Inventors: Kihong JEONG, Suwon-si (KR); Taewook KIM, Suwon-si (KR)

(73) Assignee: SAMSUNG ELECTRONICS CO., LTD., Suwon-si (KR)

(21) Appl. No.: 19/242,301

(22) Filed: Jun. 18, 2025

(30) Foreign Application Priority Data
Oct. 7, 2024 (KR) 10-2024-0135962

(51) Int. Cl. H01L 23/544; H01L 23/31; H01L 25/04

(52) U.S. Cl. CPC H10W 46/00; H10W 74/111; H10W 90/00; H10W 46/301; H10W 90/24

(57) ABSTRACT

A semiconductor package includes: a first semiconductor chip; a second semiconductor chip stacked on the first semiconductor chip to form a stepped shape in a first direction; a first alignment key on the first semiconductor chip, the first alignment key having a first surface parallel to the first direction and a second surface parallel to a second direction perpendicular to the first direction; and a second alignment key on the second semiconductor chip, the second alignment key having a third surface parallel to the first direction and a fourth surface parallel to the second direction, wherein a surface of the second semiconductor chip, which is parallel to the second direction, is aligned with the second surface of the first alignment key in the first direction, and wherein the first surface of the first alignment key is aligned with the third surface of the second alignment key in the second direction.

### CROSS-REFERENCE TO RELATED APPLICATION

This application is based on and claims priority under 35 U.S. C. § 119 to Korean Patent Application No. 10-2024-0135962, filed on Oct. 7, 2024, in the Korean Intellectual Property Office, the disclosure of which is incorporated by reference herein in its entirety.

### BACKGROUND

The present disclosure provides a semiconductor package including stacked semiconductor chips.

With the development of the electronics industry, there are growing demands for high functionality, high speed, and small size in electronic components. To address this trend, recent packaging technologies are advancing toward the mounting of a plurality of semiconductor chips in a single package.

With the recent development of the electronics industry, semiconductor packages have been developed in various ways with the objectives of reducing size, weight, and manufacturing costs. In addition, as applications thereof expand to large capacity storage means, various types of semiconductor packages are emerging. As semiconductor chips become more densely integrated, the need for precisely stacking the semiconductor chips in a more limited space is increasing.

### SUMMARY

The present disclosure provides a semiconductor package provided with an alignment key for precisely stacking semiconductor chips.

The objects of the present disclosure are not limited to the object mentioned above, but other objects not described herein will be clearly understood by those skilled in the art from the following description.

According to an aspect of the disclosure, a semiconductor package including a first semiconductor chip; a second semiconductor chip stacked on the first semiconductor chip to form a stepped shape in a first direction; a first alignment key on an active surface of the first semiconductor chip, the first alignment key having a first surface parallel to the first direction and a second surface parallel to a second direction perpendicular to the first direction; and a second alignment key on an active surface of the second semiconductor chip, the second alignment key having a third surface parallel to the first direction and a fourth surface parallel to the second direction, wherein a surface of the second semiconductor chip, which is parallel to the second direction, is aligned with the second surface of the first alignment key in the first direction, and wherein the first surface of the first alignment key is aligned with the third surface of the second alignment key in the second direction.

According to an aspect of the disclosure, a semiconductor package includes: a package substrate; a first semiconductor chip structure including a first semiconductor chip mounted on the package substrate; a second semiconductor chip structure including a second semiconductor chip stacked on the first semiconductor chip structure to form a stepped shape in a first direction; and a substrate alignment key on a surface of the package substrate, the substrate alignment key having a first alignment surface parallel to the first direction and a second alignment surface parallel to a second direction perpendicular to the first direction, wherein the first semiconductor chip structure includes a first alignment key on an active surface of the first semiconductor chip, the first alignment key having a first surface parallel to the first direction and a second surface parallel to the second direction, wherein the second semiconductor chip structure includes a second alignment key on an active surface of the second semiconductor chip, the second alignment key having a third surface parallel to the first direction and a fourth surface parallel to the second direction, wherein a surface of the first semiconductor chip, which is parallel to the second direction, is aligned with the second alignment surface of the substrate alignment key, and wherein a surface of the first semiconductor chip, which is parallel to the first direction, is aligned with the first alignment surface of the substrate alignment key.

According to an aspect of the disclosure, a semiconductor package includes a package substrate; a plurality of semiconductor chip structures including semiconductor chips stacked on the package substrate and offset from each other in an first direction to form a stepped shape; and a substrate alignment key on an active surface of the package substrate, the substrate alignment key having a first alignment surface parallel to the first direction and a second alignment surface parallel to a second direction perpendicular to the first direction, wherein each of the plurality of semiconductor chip structures includes: an alignment key, and a passivation layer extending along a surface of a respective semiconductor chip, the alignment key being buried in the passivation layer, wherein a surface, parallel to the second direction, of a semiconductor chip of a semiconductor chip structure of the plurality of semiconductor chip structures closest to the package substrate is aligned with the second alignment surface of the substrate alignment key, and a surface, parallel to the first direction, of the semiconductor chip structure of the plurality of semiconductor chip structures closest to the package substrate is aligned with the first alignment surface of the substrate alignment key.

### BRIEF DESCRIPTION OF DRAWINGS

Embodiments will be more clearly understood from the following detailed description taken in conjunction with the accompanying drawings in which:

FIG. 1 is a cross-sectional view of a semiconductor package according to one or more embodiments;

FIG. 2 is a plan view of the semiconductor package shown in FIG. 1;

FIG. 3A is an enlarged view of region “CX” of FIG. 2;

FIG. 3B is an enlarged view of a semiconductor package according to some embodiments;

FIG. 4 is an enlarged view of a semiconductor package according to some embodiments;

FIGS. 5A and 5B are enlarged views of semiconductor packages according to some embodiments;

FIGS. 6A, 6B, and 6C are enlarged views of semiconductor packages according to some embodiments;

FIGS. 7A to 7C are partial cross-sectional views of semiconductor packages according to some embodiments; and

FIGS. 8A, 8B, 9A, 9B, 10A, 10B, and 11 are cross-sectional views and plan views sequentially illustrating processes of manufacturing a semiconductor package, according to one or more embodiments.

### DETAILED DESCRIPTION

Hereinafter, embodiments are described in detail with reference to the accompanying drawings. The same reference numerals are given to the same elements in the drawings, and repeated descriptions thereof are omitted.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

A layer may be referred to as being a lower layer or an upper layer. As understood by one of ordinary skill in the art, a lower layer may be also referred to as a first layer and an upper layer may be referred to as a second layer. Furthermore, a lower layer may be referred to as a second layer and an upper layer may be referred to as a first layer.

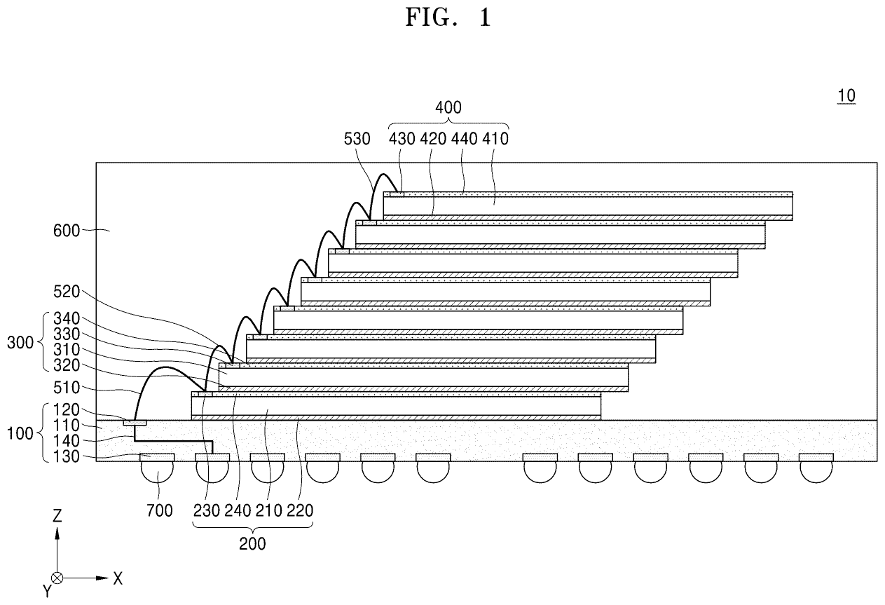

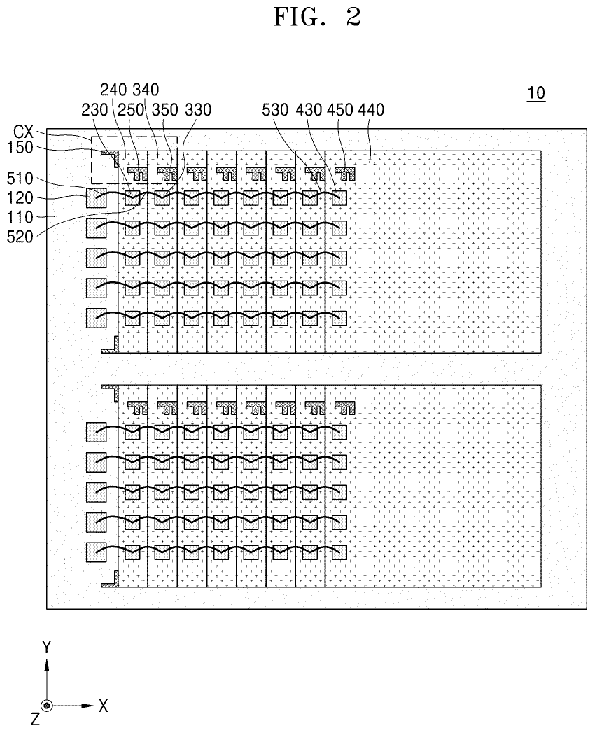

FIG. 1 is a cross-sectional view of a semiconductor package 10 according to one or more embodiments, and FIG. 2 is a plan view of the semiconductor package 10 shown in FIG. 1.

Referring to FIG. 1, the semiconductor package 10 may include a package substrate 100, a first semiconductor chip structure 200, a second semiconductor chip structure 300, a third semiconductor chip structure 400, first to third wires 510, 520, and 530, a molding layer 600, and an external connection terminal 700.

In one or more examples, the first semiconductor chip structure 200, the second semiconductor chip structure 300, and the third semiconductor chip structure 400 may be sequentially stacked on the package substrate 100. In one or more examples, the first semiconductor chip structure 200 may refer to a semiconductor chip structure located lowermost among the first to third semiconductor chip structures 200, 300, and 400 (e.g., semiconductor chip structure closes to the substrate), and the third semiconductor chip structure 400 may refer to a semiconductor chip structure located uppermost among the first to third semiconductor chip structures 200, 300, and 400 (e.g., last semiconductor chip structure in the sequence of semiconductor chip structures). Furthermore, a plurality of second semiconductor chip structures 300 may be provided, and in one or more examples, the plurality of second semiconductor chip structures 300 may refer to semiconductor chip structures arranged between the first semiconductor chip structure 200 and the third semiconductor chip structure 400.

The package substrate 100 may include a substrate body 110, an upper pad 120, a lower pad 130, an internal wiring line 140, and a substrate alignment key 150. The package substrate 100 represents a support substrate on which the first semiconductor chip structure 200, the plurality of second semiconductor chip structures 300, and the third semiconductor chip structure 400 are mounted and may include a substrate for a semiconductor package, such as a printed circuit board (PCB), a ceramic substrate, a glass substrate, a tape wiring substrate, and the like.

The substrate body 110 may include different materials depending on the type of package substrate 100. For example, when the package substrate 100 includes a PCB, the substrate body 110 may be in the form of a copper clad laminate or a copper clad laminate that has additional wiring layers laminated to one or both sides of the copper clad laminate. A lower protective layer and an upper protective layer, to which solder resist is applied, may be formed on the lower surface and the upper surface of the substrate body 110, respectively.

The upper pad 120 may be disposed on the upper surface of the substrate body 110. The upper pad 120 may provide a connection terminal that is accessible by a first wire 510 configured to electrically connect the package substrate 100 to the first semiconductor chip structure 200.

The lower pad 130 may be disposed on the lower surface of the substrate body 110. An external connection terminal 700 configured to electrically connect the semiconductor package 10 to an external device may be attached to the lower pad 130. The external connection terminal 700 may include, for example, a solder ball. As illustrated in FIG. 1, the semiconductor package may include a plurality of external connection terminals.

According to one or more embodiments, the upper pad 120 and the lower pad 130 may form an electrical path that connects the upper surface to the lower surface of the package substrate 100 via the internal wiring line 140. In one or more examples, the upper pad 120 and the lower pad 130 may each be provided in a plurality. The at least one upper pad 120 may be electrically coupled to one lower pad 130 selected from among the plurality of lower pads 130 via the internal wiring line 140 in the package substrate 100.

The upper pad 120, the lower pad 130, and the internal wiring line 140 may each include a metal material, for example, at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), carbon (C), or any other suitable material known to one of ordinary skill in the art.

According to one or more embodiments, the external connection terminal 700 may include tin (Sn), indium (In), bismuth (Bi), antimony (Sb), copper (Cu), silver (Ag), zinc (Zn), lead (Pb), and/or an alloy thereof. For example, the external connection terminal 700 may have a spherical or ball shape and include a tin-containing alloy (e.g., Sn—Ag—Cu).

The first semiconductor chip structure 200 may include a first semiconductor chip 210, a first adhesive layer 220, a first chip pad 230, a first passivation layer 240, and a first alignment key 250.

According to one or more embodiments, the first semiconductor chip 210 may include non-volatile memory, volatile memory, a microprocessor, an application processor, a controller, an image sensor, or a combination thereof.

The first adhesive layer 220 may extend along the lower surface of the first semiconductor chip 210. The first adhesive layer 220 may be configured to attach the first semiconductor chip 210 to the upper surface of the substrate body 110. According to one or more embodiments, the first adhesive layer 220 may include a die attach film (DAF). In one or more examples, a DAF may be a thin film adhesive used to connect semiconductor chips to circuit boards or chips to chips in the semiconductor packaging process.

The first chip pad 230 may be disposed on the upper surface of the first semiconductor chip 210. In one or more examples, the upper surface of the first semiconductor chip 210 may include an active surface on which semiconductor elements, such as transistors, diodes, and resistors, are integrated. The first chip pad 230 may include a conductive layer, such as metal, metal nitride, conductive carbon, and a combination thereof. For example, the at least one first chip pad 230 may include copper (Cu), cobalt (Co), aluminum (Al), tin (Sn), nickel (Ni), gold (Au), silver (Ag), tungsten (W), titanium (Ti), tantalum (Ta), rubidium (Ru), platinum (Pt), or a combination thereof. The at least one first chip pad 230 may be electrically connected to active/passive elements that are provided inside the first semiconductor chip 210.

The side surfaces of the first chip pad 230 are surrounded by the first passivation layer 240, and the upper surface of the first chip pad 230 is not covered by the first passivation layer 240 and may thus provide a connection terminal to which the first wire 510 and the second wire 520 are connected. In one or more examples, a passivation layer may be a thin layer that protects a semiconductor's active surface from an external environment. Passivation layers may be used in semiconductor manufacturing to make semiconductors more resistant to damage

The first passivation layer 240 may extend along the upper surface of the first semiconductor chip 210. The first passivation layer 240 may be configured to cover the upper surface of the first semiconductor chip 210. In one or more examples, the first passivation layer 240 may be configured to surround the side surfaces of the first chip pad 230 while not covering the upper surface of the first chip pad 230. In one or more embodiments, the first passivation layer 240 may include silicon oxide, silicon nitride, a photoresist material, photosensitive polyimide, or any other suitable material known to one of ordinary skill in the art.

A plurality of second semiconductor chip structures 300 may be provided, and the plurality of second semiconductor chip structures 300 may each include a second semiconductor chip 310, a second adhesive layer 320, a second chip pad 330, a second passivation layer 340, and a second alignment key 350.

The second semiconductor chip structure 300, which is lowermost among the plurality of second semiconductor chip structures 300 (e.g., referred to as the lowermost second semiconductor chip structure 300), may be disposed on the first semiconductor chip structure 200.

According to one or more embodiments, the second semiconductor chip 310 may be substantially the same as the first semiconductor chip 210. The second semiconductor chip 310 may have substantially the same horizontal width, substantially the same horizontal length, and substantially the same thickness as the first semiconductor chip 210.

The second adhesive layer 320 may extend along the lower surface of the second semiconductor chip 310. The second adhesive layer 320 of the lowermost second semiconductor chip structure 300 may be configured to attach the second semiconductor chip 310 to the upper surface of the first passivation layer 240. According to one or more embodiments, the second adhesive layer 320 may include substantially the same material as the first adhesive layer 220. The second adhesive layer 320 of the second semiconductor chip structure 300 that is not lowermost may be configured to attach the second semiconductor chip 310 to the upper surface of the second passivation layer 340.

The second chip pad 330 may be disposed on the upper surface of the second semiconductor chip 310. In one or more examples, the upper surface of the second semiconductor chip 310 may include an active surface on which semiconductor elements, such as transistors, diodes, and resistors, are integrated. The second chip pad 330 may include substantially the same material as the first chip pad 230. The at least one second chip pad 330 may be electrically connected to active/passive elements that are provided inside the second semiconductor chip 310. According to one or more embodiments, the second chip pad 330 may include substantially the same material as the first chip pad 230.

The side surfaces of the second chip pad 330 are surrounded by the second passivation layer 340, and the upper surface of the second chip pad 330 is not covered by the second passivation layer 340 and may thus, provide a connection terminal to which the second wire 520 is connected.

Since the second semiconductor chip structure 300 may be provided in plurality, the plurality of second semiconductor chip structures 300 may be stacked on each other to form a stepped shape in a first horizontal direction (e.g., an X direction). As the plurality of second semiconductor chip structures 300 are stacked on each other to form a stepped shape, the plurality of second semiconductor chip structures 300 may be aligned such that each of the second chip pads 330 is not covered by another second semiconductor chip 310 but exposed. In one or more examples, each semiconductor chip structure illustrated in FIG. 1 may be shifted along the X axis to form the stepped structure. Each semiconductor chip structure may be shifted along the X axis by an equal amount. In one or more examples, at least one semiconductor chip structure may be shifted along the X axis by an amount that is different than an amount the other semiconductor chips are shifted.

The second passivation layer 340 may extend along the upper surface of the second semiconductor chip 310. The second passivation layer 340 may be configured to cover the upper surface of the second semiconductor chip 310. In one or more examples, the second passivation layer 340 may be configured to surround the side surfaces of the second chip pad 330 while not covering the upper surface of the second chip pad 330. In one or more embodiments, the material provided in the second passivation layer 340 may be substantially the same as the material provided in the first passivation layer 240.

The third semiconductor chip structure 400 may include a third semiconductor chip 410, a third adhesive layer 420, a third chip pad 430, a third passivation layer 440, and a third alignment key 450.

The third semiconductor chip structure 400 may be disposed on the second semiconductor chip structure 300, which is uppermost among the plurality of second semiconductor chip structures 300 (hereinafter, referred to as the uppermost second semiconductor chip 300).

According to one or more embodiments, the third semiconductor chip 410 may be substantially the same as the first semiconductor chip 210. The third semiconductor chip 410 may have substantially the same horizontal width, substantially the same horizontal length, and substantially the same thickness as the first semiconductor chip 210.

The third adhesive layer 420 may extend along the lower surface of the third semiconductor chip 410. The third adhesive layer 420 may be configured to attach the third semiconductor chip 410 to the upper surface of the second passivation layer 340 of the uppermost second semiconductor chip structure 300. According to one or more embodiments, the third adhesive layer 420 may include substantially the same material as the first adhesive layer 220.

The third chip pad 430 may be disposed on the upper surface of the third semiconductor chip 410. In one or more examples, the upper surface of the third semiconductor chip 410 may include an active surface on which semiconductor elements, such as transistors, diodes, and resistors, are integrated. The third chip pad 430 may include substantially the same material as the first chip pad 230. The at least one third chip pad 430 may be electrically connected to active/passive elements that are provided inside the third semiconductor chip 410. According to one or more embodiments, the third chip pad 430 may include substantially the same material as the first chip pad 230.

The side surfaces of the third chip pad 430 are surrounded by the third passivation layer 440, and the upper surface of the third chip pad 430 is not covered by the third passivation layer 440 and may thus, provide a connection terminal to which the third wire 530 is connected.

According to one or more embodiments, the first semiconductor chip structure 200 may be electrically connected to the package substrate 100 by the first wire 510. One end of the first wire 510 may be connected to the upper pad 120 of the package substrate 100, and the other end of the first wire 510 opposite to the one end of the first wire 510 may be connected to the upper pad 120 of the first semiconductor chip structure 200.

The second wire 520 may be provided in plurality, and the plurality of second semiconductor chip structures 300 at different vertical levels may be electrically connected to each other by the second wires 520. In addition, the lowermost second semiconductor chip structure 300 among the plurality of second semiconductor chip structures 300 may also be electrically connected to the first semiconductor chip structure 200 by the second wire 520.

Specifically, one end of the second wire 520 other than the lowermost wire among the plurality of second wires 520 may be connected to the second chip pad 330 of the second semiconductor chip structure 300 disposed below, and the other end of the second wire 520 opposite to the one end of the second wire 520 may be connected to the second chip pad 330 of the second semiconductor chip structure 300 disposed above. In addition, one end of the second wire 520 that is lowermost among the plurality of second wires 520 may be connected to the first chip pad 230, and the other end of the second wire 520 opposite to the one end of the second wire 520 may be connected to the second chip pad 330 that is lowermost (e.g., referred to as the lowermost second chip pad 330).

According to one or more embodiments, the third semiconductor chip structure 400 may be electrically connected to the second semiconductor chip structure 300 by the third wire 530. One end of the third wire 530 may be connected to the third chip pad 430 of the uppermost second semiconductor chip structure 300, and the other end of the third wire 530 opposite to the one end of the third wire 530 may be connected to the third chip pad 430 of the third semiconductor chip structure 400.

The first wire 510, the plurality of second wires 520, and the third wire 530 may include a conductive material. The conductive material may include, for example, at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C).

According to one or more embodiments, the molding layer 600 may be provided on the package substrate 100. The molding layer 600 may be provided on the upper surface of the package substrate 100 and configured to seal the first semiconductor chip structure 200, the plurality of second semiconductor chip structures 300, and the third semiconductor chip structure 400. The vertical level of the uppermost portion of the third wire 530 may be higher than the vertical level of the upper surface of the third semiconductor chip structure 400. In one or more examples, the molding layer 600 may be configured to seal the third wire 530 such that the uppermost portion of the third wire 530 is not exposed. The molding layer 600 may include an epoxy molding compound. The molding layer 600 may be aligned with the package substrate 100 such that the side surface of the molding layer 600 is coplanar with the side surface of the package substrate 100.

The plan view of FIG. 2 illustrates the substrate alignment key 150 of the package substrate 100, the first alignment key 250 of the first semiconductor chip structure 200, the second alignment key 350 of the second semiconductor chip structure 300, and the third alignment key 450 of the third semiconductor chip structure 400.

The substrate alignment key 150 may be disposed on the upper surface of the package substrate 100, and the first alignment key 250 may be disposed on the upper surface of the first semiconductor chip 210. In one or more examples, the plurality of second alignment keys 350 may be respectively disposed on the upper surfaces of the second semiconductor chips 310, and the third alignment key 450 may be disposed on the upper surface of the third semiconductor chip 410.

The first semiconductor chip structure 200 may be disposed on the package substrate 100, and the plurality of second semiconductor chip structures 300 may be disposed on the first semiconductor chip structure 200. In one or more examples, the third semiconductor chip structure 400 may be disposed on the uppermost second semiconductor chip structure 300 among the plurality of second semiconductor chip structures 300.

The plurality of second semiconductor chip structures 300 may be disposed on the first semiconductor chip structure 200 and offset from each other in the first horizontal direction (e.g., the X direction). In one or more examples, the third semiconductor chip structure 400 may be disposed on the uppermost second semiconductor chip structure 300 and offset therefrom in the first horizontal direction (e.g., the X direction).

In a plan view, the upper pad 120, the first chip pad 230, the plurality of second chip pads 330, and the third chip pad 430 may be arranged side by side in the first horizontal direction (e.g., the X direction).

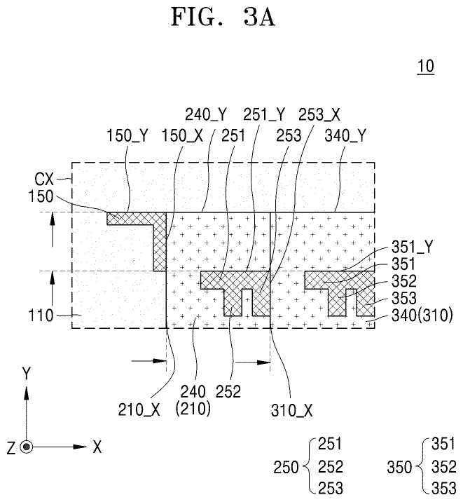

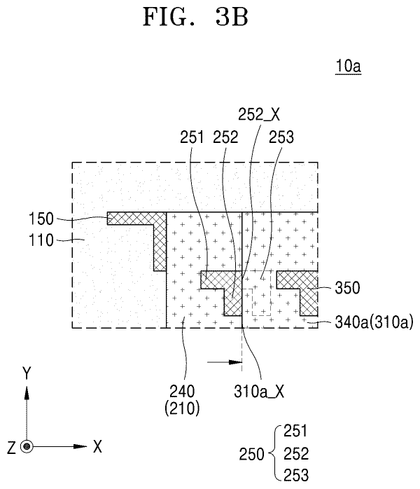

FIG. 3A is an enlarged view of region “CX” of FIG. 2.

Referring to FIG. 3A together with FIG. 1, the substrate alignment key 150 may have a first alignment surface 150_Y that is parallel to the first horizontal direction (e.g., the X direction) and perpendicular to a second horizontal direction (e.g., a Y direction). A surface 240_Y of the first semiconductor chip 210, which is parallel to the first horizontal direction (e.g., the X direction), may be aligned with the first alignment surface 150_Y of the substrate alignment key 150. In one or more examples, a surface 340_Y of the second semiconductor chip 310, which is parallel to the first horizontal direction (e.g., the X direction), may be aligned with the first alignment surface 150_Y of the substrate alignment key 150. In addition, as shown in FIG. 2, a surface of the third semiconductor chip 410, which is parallel to the first horizontal direction (e.g., the X direction), may be aligned with the first alignment surface 150_Y of the substrate alignment key 150. For example, the first alignment surface 150_Y of the substrate alignment key 150 may provide a reference for an alignment position in the second horizontal direction (e.g., the Y direction) when the first semiconductor chip structure 200, the second semiconductor chip structure 300, and the third semiconductor chip structure 400 are mounted on the package substrate 100.

According to one or more embodiments, the substrate alignment key 150 may have a second alignment surface 150_X that is perpendicular to the first horizontal direction (e.g., the X direction) and parallel to the second horizontal direction (e.g., the Y direction). A surface 210_X of the first semiconductor chip 210, which is parallel to the second horizontal direction (e.g., the Y direction), may be aligned with the second alignment surface 150_X of the substrate alignment key 150. For example, the second alignment surface 150_X of the substrate alignment key 150 may provide a reference for an alignment position in the first horizontal direction (e.g., the X direction) when the first semiconductor chip structure 200 is mounted on the package substrate 100.

The first alignment key 250 may be disposed on the upper surface of the first semiconductor chip 210. In one or more examples, the upper surface of the first semiconductor chip 210 represents an active surface of the first semiconductor chip 210. The first alignment key 250 may include a first extension 251 extending in the first horizontal direction (e.g., the X direction), a second extension 252 connected to the first extension 251 and extending in a direction opposite to the second horizontal direction (e.g., the Y direction), and a third extension 253 extending from an end of the first extension 251 in the direction opposite to the second horizontal direction (e.g., the Y direction). In one or more examples, the second extension 252 and the third extension 253 may extend in a direction away from the side surface of the first semiconductor chip 210, which is closest to the second extension 252 and the third extension 253 and parallel to the first horizontal direction (e.g., the X direction).

The second alignment key 350 may be disposed on the upper surface of the second semiconductor chip 310. In one or more examples, the upper surface of the second semiconductor chip 310 represents an active surface of the second semiconductor chip 310. The second alignment key 350 may include a fourth extension 351 extending in the first horizontal direction (e.g., the X direction), a fifth extension 352 connected to the fourth extension 351 and extending in the direction opposite to the second horizontal direction (e.g., the Y direction), and a sixth extension 353 extending from an end of the fourth extension 351 in the direction opposite to the second horizontal direction (e.g., the Y direction). In one or more examples, the fifth extension 352 and the sixth extension 353 may extend in a direction away from the side surface of the second semiconductor chip 310, which is closest to the fifth extension 352 and the sixth extension 353 and parallel to the first horizontal direction (e.g., the X direction). The first alignment key 250 may have substantially the same shape as the second alignment key 350. Although FIG. 3A illustrates that the alignment keys 250 and 350 have two extensions, the embodiments of the present disclosure are not limited to these configurations. For example, an alignment key may include more than two extensions. Furthermore, the extensions of each alignment key may have the same length, or one extension of an alignment key may be different than another extension of an alignment key.

The first extension 251 of the first alignment key 250 may have a first surface 251_Y that is parallel to the first horizontal direction (e.g., the X direction) and perpendicular to the second horizontal direction (e.g., the Y direction). The first surface 251_Y is defined as the widest surface among surfaces of the first alignment key 250 that are parallel to the first horizontal direction (e.g., the X direction). The fourth extension 351 of the second alignment key 350 may have a surface 351_Y parallel to the first horizontal direction (e.g., the X direction) and perpendicular to the second horizontal direction (e.g., the Y direction), and the surface 351_Y may be aligned with the first surface 251_Y of the first extension 251. The surface 351_Y of the fourth extension 351, which is parallel to the first horizontal direction (e.g., the X direction) as described above, is defined as the widest surface among surfaces of the second alignment key 350 that are parallel to the first horizontal direction (e.g., the X direction).

The third extension 253 of the first alignment key 250 may have a second surface 253_X that is perpendicular to the first horizontal direction (e.g., the X direction) and parallel to the second horizontal direction (e.g., the Y direction). The second surface 253_X is defined as the widest surface among surfaces of the first alignment key 250 that are parallel to the second horizontal direction (e.g., the Y direction). The second semiconductor chip 310 may have a side surface 310_X perpendicular to the first horizontal direction (e.g., the X direction) and parallel to the second horizontal direction (e.g., the Y direction), and the side surface 310_X may be aligned with the second surface 253_X of the third extension 253. The side surface 310_X of the second semiconductor chip 310 described above may represent a surface that faces the first alignment key 250 in a plan view.

For example, the first surface 251_Y of the first extension 251 may provide a reference for an alignment position in the second horizontal direction (e.g., the Y direction) when the second semiconductor chip structure 300 is mounted on the first semiconductor chip structure 200. In one or more examples, the second surface 253_X of the third extension 253 may provide a reference for an alignment position in the first horizontal direction (e.g., the X direction) when the second semiconductor chip structure 300 is mounted on the first semiconductor chip structure 200.

According to one or more embodiments, the substrate alignment key 150 does not overlap the first semiconductor chip 210 in a vertical direction (e.g., a Z direction), and the first alignment key 250 does not overlap the second semiconductor chip 310 in the vertical direction (e.g., the Z direction). In one or more examples, the second alignment key 350 does not overlap, in the vertical direction (e.g., the Z direction), another second semiconductor chip 310 that is stacked on the second semiconductor chip structure 300 that provides the second alignment key 350.

Although only one second semiconductor chip 310 and one second alignment key 350 are shown in FIG. 3A, the descriptions given with reference to FIG. 3A may also apply to a process in which the plurality of second semiconductor chips 310 are stacked in an offset manner. In one or more examples, the second semiconductor chip structure 300 located at a lower position among the plurality of second semiconductor chip structures 300 may correspond to the first semiconductor chip structure 200, and the second semiconductor chip structure 300 located at an upper position among the plurality of second semiconductor chip structures 300 may correspond to the second semiconductor chip structure 300 shown in FIG. 3A. This may apply to the descriptions of semiconductor packages 10a, 20, 30, 30a, 40, 40a, and 40b illustrated in FIGS. 3B, 4, 5A, 5B, 6A, 6B, and 6C, respectively, which are described below.

FIG. 3B is an enlarged view of a semiconductor package 10a according to some embodiments.

The semiconductor package 10a shown in FIG. 3B is substantially the same as or similar to the semiconductor package 10 shown in FIG. 3A, except that a second semiconductor chip 310a is aligned with a second extension 252 of a first alignment key 250 rather than a third extension 253. Therefore, descriptions of the components already given above with reference to FIG. 3A are omitted or briefly given below. The second semiconductor chip 310a includes a second passivation layer 340a.

The second extension 252 of the first alignment key 250 may have a second surface 252_X that is perpendicular to a first horizontal direction (e.g., an X direction) and parallel to a second horizontal direction (e.g., a Y direction). The second surface 252_X may represent a surface that faces the second semiconductor chip 310a among surfaces of the second extension 252 in a plan view. The second semiconductor chip 310a may have a side surface 310a_X perpendicular to the first horizontal direction (e.g., the X direction) and parallel to the second horizontal direction (e.g., the Y direction), and the side surface 310a_X may be aligned with the second surface 252_X of the second extension 252. The side surface 310a_X of the second semiconductor chip 310a described above may represent a surface that faces the first alignment key 250 in a plan view.

For example, the second surface 252_X of the second extension 252 may provide a reference for an alignment position in the first horizontal direction (e.g., the X direction) when a second semiconductor chip structure 300 is mounted on a first semiconductor chip structure 200. In the semiconductor package 10a shown in FIG. 3B, the second semiconductor chip structure 300 is aligned with the second extension 252 rather than the third extension 253, and thus, the second semiconductor chip 310 and the third semiconductor chip 410 may be stacked more compactly.

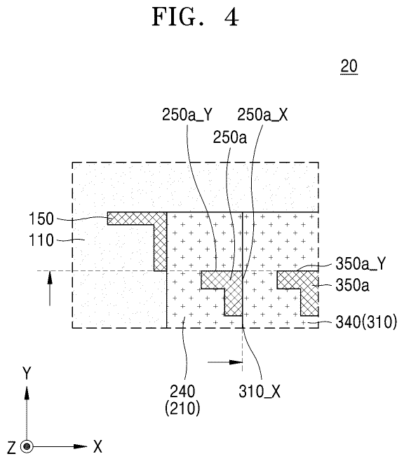

FIG. 4 is an enlarged view of a semiconductor package 20 according to some embodiments.

The semiconductor package 20 shown in FIG. 4 is substantially the same as or similar to the semiconductor package 10 shown in FIG. 3A, except that a first alignment key 250a and a second alignment key 350a have different shapes than alignment keys 252 and 352, respectively. Therefore, descriptions of the components already given above with reference to FIG. 3A are omitted or briefly given below. In one or more examples, the shape of a third alignment key located on a third semiconductor chip is the same as the shape of each of the first alignment key 250a and the second alignment key 350a.

The first alignment key 250a may have a first surface 250a_Y that is parallel to the first horizontal direction (e.g., the X direction) and perpendicular to the second horizontal direction (e.g., the Y direction). The first surface 250a_Y is defined as the widest surface among surfaces of the first alignment key 250a that are parallel to the first horizontal direction (e.g., the X direction). The second alignment key 350a may have a surface 350a_Y parallel to the first horizontal direction (e.g., the X direction) and perpendicular to the second horizontal direction (e.g., the Y direction), and the surface 350a_Y may be aligned with the first surface 250a_Y of the first alignment key 250a. The first surface 250a_Y described above is defined as the widest surface among surfaces of the second alignment key 350a that are parallel to the first horizontal direction (e.g., the X direction).

The first alignment key 250a may have a second surface 250a_X that is perpendicular to the first horizontal direction (e.g., the X direction) and parallel to the second horizontal direction (e.g., the Y direction). The second surface 250a_X is defined as the widest surface among surfaces of the first alignment key 250a that are parallel to the second horizontal direction (e.g., the Y direction). The second semiconductor chip 310 may have a side surface 310_X perpendicular to the first horizontal direction (e.g., the X direction) and parallel to the second horizontal direction (e.g., the Y direction), and the side surface 310_X may be aligned with the second surface 250a_X of the first alignment key 250a. The side surface 310_X of the second semiconductor chip 310 described above may represent a surface that faces the first alignment key 250a in a plan view.

According to one or more embodiments, the first alignment key 250a does not overlap the second semiconductor chip 310 in a vertical direction (e.g., a Z direction). In one or more examples, the second alignment key 350a does not overlap, in the vertical direction (e.g., the Z direction), another second semiconductor chip 310 that is stacked on the second semiconductor chip 310 on which the second alignment key 350a is disposed.

For example, the first surface 250a_Y of the first alignment key 250a may provide a reference for an alignment position in the second horizontal direction (e.g., the Y direction) when the second semiconductor chip structure 300 is mounted on the first semiconductor chip structure 200. In one or more examples, the second surface 250a_X of the first alignment key 250a may provide a reference for an alignment position in the first horizontal direction (e.g., the X direction) when the second semiconductor chip structure 300 is mounted on the first semiconductor chip structure 200.

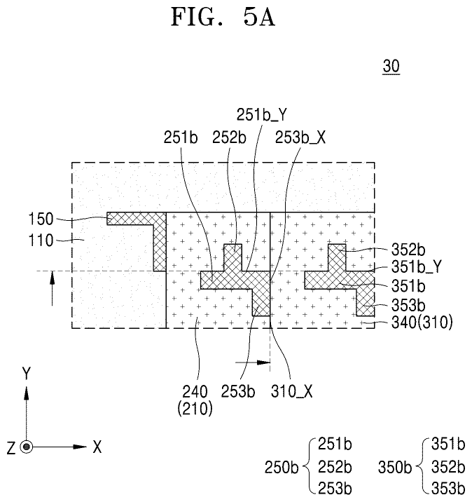

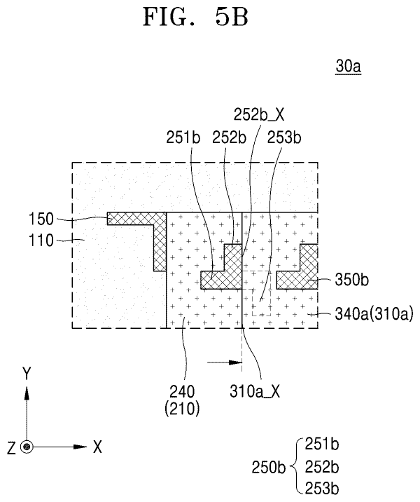

FIGS. 5A and 5B are enlarged views of semiconductor packages 30 and 30a, respectively, according to some embodiments.

The semiconductor package 30 shown in FIG. 5A is substantially the same as or similar to the semiconductor package 10 shown in FIG. 3A, except that a first alignment key 250b and a second alignment key 350b have different shapes than the alignment keys 252 and 352, respectively, illustrated in FIG. 3A. Therefore, descriptions of the components already given above with reference to FIG. 3A are omitted or briefly given below. In one or more examples, although not shown in detail, the shape of a third alignment key located on a third semiconductor chip is the same as the shape of each of the first alignment key 250b and the second alignment key 350b.

The first alignment key 250b may include a first extension 251b extending in a first horizontal direction (e.g., an X direction), a second extension 252b connected to the first extension 251b and extending in a second horizontal direction (e.g., a Y direction), and a third extension 253b extending from an end of the first extension 251b in a direction opposite to the second horizontal direction (e.g., the Y direction). In one or more examples, the second extension 252b may extend toward the outer perimeter of the first semiconductor chip 210, and the third extension 253b may extend in a direction opposite to the direction in which the second extension 252b extends. In one or more examples, each of the first extension 251b, second extension 252b, and the third extension 253b may be the same length. In one or more examples, at least one of the first extension 251b, second extension 252b, and the third extension 253b may have a different length than the other extensions.

The second alignment key 350b may include a fourth extension 351b extending in the first horizontal direction (e.g., the X direction), a fifth extension 352b connected to the fourth extension 351b and extending in the second horizontal direction (e.g., the Y direction), and a sixth extension 353b extending from an end of the fourth extension 351b in a direction opposite to the second horizontal direction (e.g., the Y direction). In one or more examples, the fifth extension 352b may extend toward the outer perimeter of the second semiconductor chip 310, and the sixth extension 353b may extend in a direction opposite to the direction in which the fifth extension 352b extends. The first alignment key 250b may have substantially the same shape as the second alignment key 350b.

The first extension 251b of the first alignment key 250b may have a first surface 251b_Y that is parallel to the first horizontal direction (e.g., the X direction) and perpendicular to the second horizontal direction (e.g., the Y direction). The first surface 251b_Y is defined as a surface that faces the outer perimeter of the first semiconductor chip 210 among surfaces of the first alignment key 250b that are parallel to the first horizontal direction (e.g., the X direction). The fourth extension 351b of the second alignment key 350b may have a surface 351b_Y parallel to the first horizontal direction (e.g., the X direction) and perpendicular to the second horizontal direction (e.g., the Y direction), and the surface 351b_Y may be aligned with the first surface 251b_Y of the first extension 251b. The surface 351b_Y of the fourth extension 351b, which is parallel to the first horizontal direction (e.g., the X direction) as described above, is defined as a surface that faces the outer perimeter of the second semiconductor chip among the surfaces of the second alignment key 350b that are parallel to the first horizontal direction (e.g., the X direction).

The third extension 253b of the first alignment key 250b may have a second surface 253b_X that is perpendicular to the first horizontal direction (e.g., the X direction) and parallel to the second horizontal direction (e.g., the Y direction). The second surface 253b_X is defined as the widest surface among surfaces of the first alignment key 250b that are parallel to the second horizontal direction (e.g., the Y direction). The second semiconductor chip 310 may have a side surface 310_X perpendicular to the first horizontal direction (e.g., the X direction) and parallel to the second horizontal direction (e.g., the Y direction), and the side surface 310_X may be aligned with the second surface 253b_X of the third extension 253b. The side surface 310_X of the second semiconductor chip 310 described above may represent a surface that faces the first alignment key 250b in a plan view.

According to one or more embodiments, the first alignment key 250b does not overlap the second semiconductor chip 310 in a vertical direction (e.g., a Z direction). In one or more examples, the second alignment key 350b does not overlap, in the vertical direction (e.g., the Z direction), another second semiconductor chip 310 that is stacked on the second semiconductor chip 310 on which the second alignment key 350b is disposed.

For example, the first surface 251b_Y of the first extension 251b may provide a reference for an alignment position in the second horizontal direction (e.g., the Y direction) when the second semiconductor chip structure 300 is mounted on the first semiconductor chip structure 200. In one or more examples, the second surface 253b_X of the third extension 253b may provide a reference for an alignment position in the first horizontal direction (e.g., the X direction) when the second semiconductor chip structure 300 is mounted on the first semiconductor chip structure 200.

The semiconductor package 30a shown in FIG. 5B is substantially the same as or similar to the semiconductor package 30 shown in FIG. 5A, except that a second semiconductor chip 310 is aligned with a second extension 252b of a first alignment key 250b rather than a third extension 253b. Therefore, descriptions of the components already given above with reference to FIG. 5A are omitted or briefly given below.

The second extension 252b of the first alignment key 250b may have a second surface 252b_X that is perpendicular to a first horizontal direction (e. g,. an X direction) and parallel to a second horizontal direction (e.g., a Y direction). The second surface 252b_X may represent a surface that faces a second semiconductor chip 310a among surfaces of the second extension 252b in a plan view. The second semiconductor chip 310a may have a side surface 310a_X perpendicular to the first horizontal direction (e.g., the X direction) and parallel to the second horizontal direction (e.g., the Y direction), and the side surface 310a_X may be aligned with the second surface 252b_X of the second extension 252. The side surface 310a_X of the second semiconductor chip 310a described above may represent a surface that faces the first alignment key 250b in a plan view.

For example, the second surface 252b_X of the second extension 252b may provide a reference for an alignment position in the first horizontal direction (e.g., the X direction) when a second semiconductor chip structure 300 is mounted on a first semiconductor chip structure 200. In the semiconductor package 30a shown in FIG. 5B, the second semiconductor chip structure 300 is aligned with the second extension 252b rather than the third extension 253b, and thus, the second semiconductor chip 310a and a third semiconductor chip 410 may be stacked more compactly.

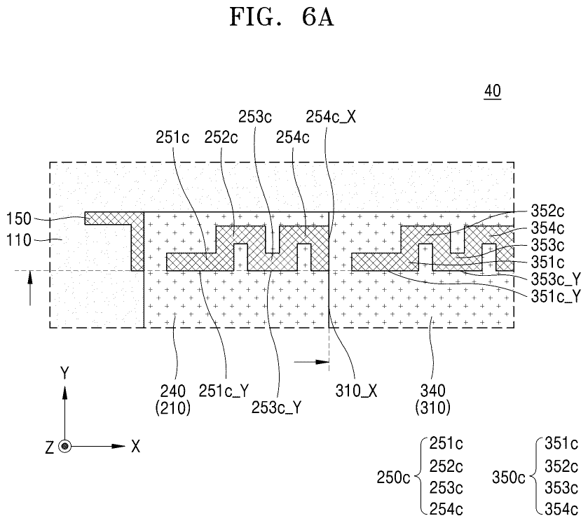

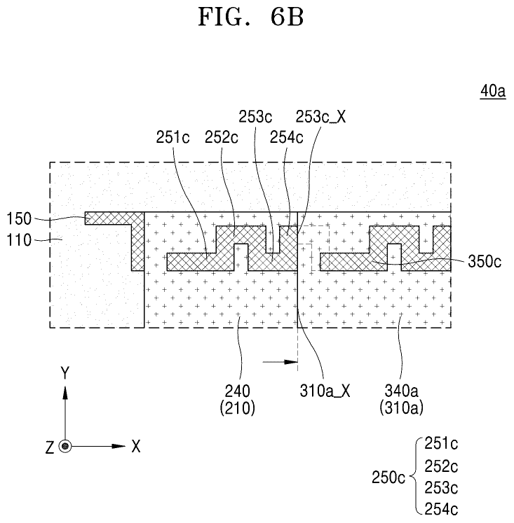

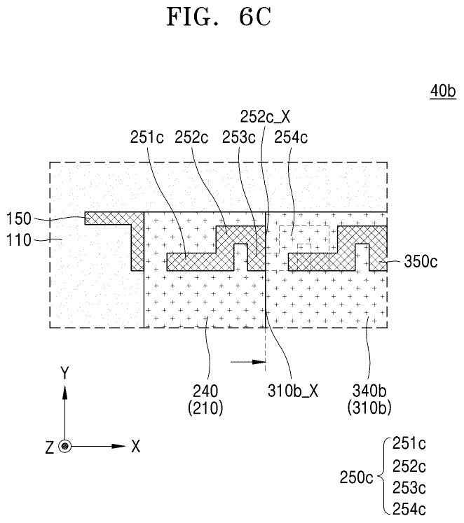

FIGS. 6A, 6B, and 6C are enlarged views of semiconductor packages 40, 40a, and 40b, respectively, according to some embodiments.

The semiconductor package 40 shown in FIG. 6A is substantially the same as or similar to the semiconductor package 10 shown in FIG. 3A, except that a first alignment key 250c and a second alignment key 350c have different shapes than the alignment keys 252 and 352, respectively, in FIG. 3A. Therefore, descriptions of the components already given above with reference to FIG. 3A are omitted or briefly given below. In one or more examples, although not shown in detail, the shape of a third alignment key located on a third semiconductor chip is the same as the shape of each of the first alignment key 250c and the second alignment key 350c.

The first alignment key 250c may include a first extension 251c, a first pattern 252c, a second pattern 253c, and a third pattern 254c. The first extension 251c may extend in a first horizontal direction (e.g., an X direction) on a first semiconductor chip 210. The first pattern 252c may have a U-shape, of which the widest surface faces the closest side surface of the first semiconductor chip 210. The second pattern 253c may have a U-shape, of which the widest surface faces in a direction opposite to the closest side surface of the first semiconductor chip 210. The third pattern 254c may have a U-shape, of which the widest surface faces the closest side surface of the first semiconductor chip 210. The first extension 251c, the first pattern 252c, the second pattern 253c, and the third pattern 254c may be integrated with each other to form a series of consecutive components. As used herein, the closest side surface of the first semiconductor chip 210 represents a surface perpendicular to a second horizontal direction (e.g., a Y direction).

The second alignment key 350c may include a second extension 351c, a fourth pattern 352c, a fifth pattern 353c, and a sixth pattern 354c. The second extension 351c may extend in the first horizontal direction (e.g., the X direction) on a second semiconductor chip 310. The fourth pattern 352c may have a U-shape, of which the widest surface faces the closest side surface of the second semiconductor chip 310. The fifth pattern 353c may have a U-shape, of which the widest surface faces in a direction opposite to the closest side surface of the second semiconductor chip 310. The sixth pattern 354c may have a U-shape, of which the widest surface faces the closest side surface of the second semiconductor chip 310. The second extension 351c, the fourth pattern 352c, the fifth pattern 353c, and the sixth pattern 354c may be integrated with each other to form a series of consecutive components. As used herein, the closest side surface of the second semiconductor chip 310 represents a surface perpendicular to the second horizontal direction (e.g., the Y direction).

The first extension 251c of the first alignment key 250c may have a first surface 251c_Y that is parallel to the first horizontal direction (e.g., the X direction) and perpendicular to the second horizontal direction (e.g., the Y direction). The first surface 251c_Y is defined as the widest surface among surfaces of the first extension 251c that are parallel to the first horizontal direction (e.g., the X direction). The second extension 351c of the second alignment key 350c may have a surface 351c_Y parallel to the first horizontal direction (e.g., the X direction) and perpendicular to the second horizontal direction (e.g., the Y direction), and the surface 351c_Y may be aligned with the first surface 251c_Y of the first extension 251c. The surface 351c_Y of the second extension 351c, which is parallel to the first horizontal direction (e.g., the X direction) as described above, is defined as the widest surface among surfaces of the second extension 351c that are parallel to the first horizontal direction (e.g., the X direction).

The third pattern 254c of the first alignment key 250c may have a second surface 254c_X that is perpendicular to the first horizontal direction (e.g., the X direction) and parallel to the second horizontal direction (e.g., the Y direction). The second surface 254c_X is defined as the widest surface among surfaces of the third pattern 254c that are parallel to the second horizontal direction (e.g., the Y direction). The second semiconductor chip 310 may have a side surface 310_X perpendicular to the first horizontal direction (e.g., the X direction) and parallel to the second horizontal direction (e.g., the Y direction), and the side surface 310_X may be aligned with the second surface 254c_X of the third pattern 254c. The side surface 310_X of the second semiconductor chip 310 described above may represent a surface that faces the first alignment key 250c in a plan view.

According to one or more embodiments, the first alignment key 250c does not overlap the second semiconductor chip 310 in a vertical direction (e.g., a Z direction). In one or more examples, the second alignment key 350c does not overlap, in the vertical direction (e.g., the Z direction), another second semiconductor chip 310 that is stacked on the second semiconductor chip 310 on which the second alignment key 350c is disposed.

For example, the first surface 251c_Y of the first extension 251c may provide a reference for an alignment position in the second horizontal direction (e.g., the Y direction) when a second semiconductor chip structure 300 is mounted on a first semiconductor chip structure 200. In one or more examples, the second surface 254c_X of the third pattern 254c may provide a reference for an alignment position in the first horizontal direction (e.g., the X direction) when the second semiconductor chip structure 300 is mounted on the first semiconductor chip structure 200.

The semiconductor package 40a shown in FIG. 6B is substantially the same as or similar to the semiconductor package 40 shown in FIG. 6A, except that a second semiconductor chip 310 is aligned with a second pattern 253c rather than a third pattern 254c of a first alignment key 250c. Therefore, descriptions of the components already given above with reference to FIG. 6A are omitted or briefly given below.

A second pattern 253c of the first alignment key 250c may have a second surface 253c_X that is perpendicular to a first horizontal direction (e.g., an X direction) and parallel to a second horizontal direction (a Y direction). The second surface 253c_X may represent the widest surface that faces a second semiconductor chip 310a among surfaces of the second pattern 253c in a plan view. The second semiconductor chip 310a may have a side surface 310a_X perpendicular to the first horizontal direction (e.g., the X direction) and parallel to the second horizontal direction (e.g., the Y direction), and the side surface 310a_X may be aligned with the second surface 253c_X of the second pattern 253c. The side surface 310a_X of the second semiconductor chip 310a described above may represent a surface that faces the first alignment key 250c in a plan view.

For example, the second surface 253c_X of the second pattern 253c may provide a reference for an alignment position in the first horizontal direction (e.g., the X direction) when a second semiconductor chip structure 300 is mounted on a first semiconductor chip structure 200. In the semiconductor package 40a shown in FIG. 6B, the second semiconductor chip structure 300 is aligned with the second pattern 253c rather than the third pattern 254c, and thus, the second semiconductor chip 310 and a third semiconductor chip 410 may be stacked more compactly.

The semiconductor package 40b shown in FIG. 6C is substantially the same as or similar to the semiconductor package 40 shown in FIG. 6A, except that a second semiconductor chip 310b is aligned with a first pattern 252c rather than a third pattern 254c of a first alignment key 250c. Therefore, descriptions of the components already given above with reference to FIG. 6A are omitted or briefly given below.

The first alignment key 250c of the first alignment key 250c may have a second surface 252c_X that is perpendicular to a first horizontal direction (e.g., an X direction) and parallel to a second horizontal direction (a Y direction). The second surface 252c_X may represent the widest surface that faces the second semiconductor chip 310b among surfaces of the first pattern 252c in a plan view. The second semiconductor chip 310b may have a side surface 310b_X perpendicular to the first horizontal direction (e.g., the X direction) and parallel to the second horizontal direction (e.g., the Y direction), and the side surface 310b_X may be aligned with the second surface 252c_X of the first pattern 252c. The side surface 310b_X of the second semiconductor chip 310b described above may represent a surface that faces the first alignment key 250c in a plan view.

For example, the second surface 252c_X of the first pattern 252c may provide a reference for an alignment position in the first horizontal direction (e.g., the X direction) when a second semiconductor chip structure 300 is mounted on a first semiconductor chip structure 200. In the semiconductor package 40b shown in FIG. 6C, the second semiconductor chip structure 300 is aligned with the first pattern 252c rather than the third pattern 254c, and thus, the second semiconductor chip 310 and a third semiconductor chip 410 may be stacked more compactly.

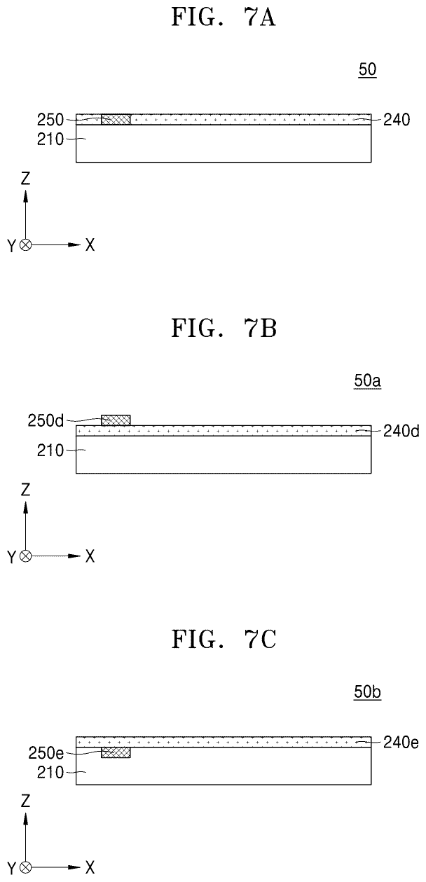

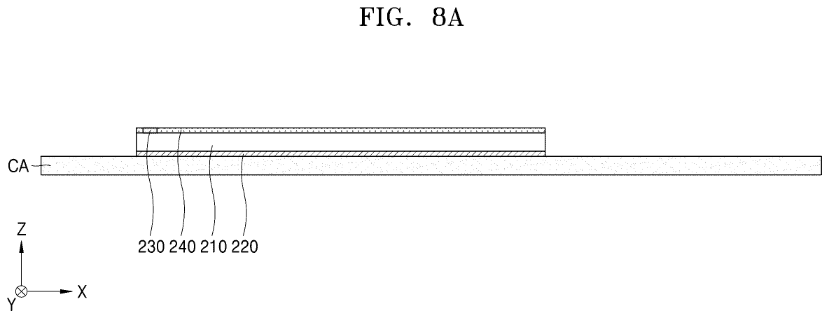

FIGS. 7A to 7C are partial cross-sectional views of semiconductor packages 50, 50a, and 50b, respectively, according to some embodiments.

Although FIGS. 7A to 7C focus on a first alignment key 250, the description thereof may also apply to the second alignment key 350 (see FIG. 2) and the third alignment key 450 (see FIG. 2).

Referring to FIG. 7A, in the semiconductor package 50 of FIG. 7A, the first alignment key 250 may be disposed on the upper surface of a first semiconductor chip 210. In addition, a first passivation layer 240 may also be disposed on the upper surface of the first semiconductor chip 210. In one or more examples, side surfaces of the first alignment key 250 may be surrounded by the first passivation layer 240. In one or more examples, the upper surface of the first alignment key 250 may be exposed by the first passivation layer 240.

Referring to FIG. 7B, in the semiconductor package 50a of FIG. 7B, a first passivation layer 240d may be disposed on the upper surface of the first semiconductor chip 210. In one or more examples, a first alignment key 250d may be disposed on the first passivation layer 240d. In one or more examples, the first passivation layer 240d does not surround the side surfaces of the first alignment key 250d.

Referring to FIG. 7C, in the semiconductor package 50b of FIG. 7C, a first alignment key 250e may be located inside a first semiconductor chip 210. In one or more examples, the upper surface of the first alignment key 250e may be coplanar with the upper surface of the first semiconductor chip 210. In addition, a first passivation layer 240e may be disposed on the first semiconductor chip 210. The first passivation layer 240e may cover the upper surface of the first alignment key 250e.

The first passivation layer 240 shown in FIG. 7A and the first passivation layer 240d shown in FIG. 7B may also include an opaque insulating material, depending on the embodiment. However, a first passivation layer 240e shown in FIG. 7C may not include an opaque insulating material, but may include a transparent or translucent insulating material.

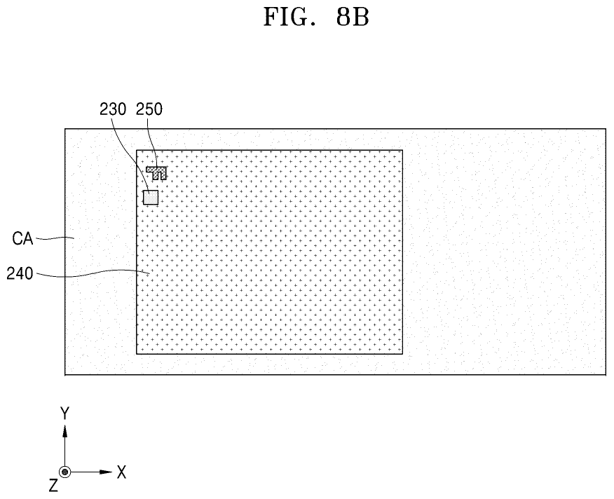

FIGS. 8A, 8B, 9A, 9B, 10A, 10B, and 11 are cross-sectional views and plan views sequentially illustrating processes of manufacturing a semiconductor package, according to one or more embodiments.

Referring to FIGS. 8A and 8B, first, a first semiconductor chip 210 with a first adhesive layer 220 disposed on the lower surface thereof may be attached to a carrier substrate CA. The carrier substrate CA may include an insulating substrate containing glass or polymer, or a conductive substrate containing metal.

The first adhesive layer 220 extending along the lower surface of the first semiconductor chip 210 may be attached to the upper surface of the carrier substrate CA.

A first chip pad 230 and a first alignment key 250 may be attached to the upper surface of the first semiconductor chip 210. In one or more examples, the first chip pad 230 and the first alignment key 250 may be formed on an outer perimeter of the first semiconductor chip 210 in a plan view.

The first chip pad 230 and the first alignment key 250 may be formed in Fabrication (Fab) in which the first semiconductor chip structure 200 is manufactured. Alignment keys for aligning semiconductor chips may also be attached to the semiconductor chips during the manufacturing process, allowing for more precise arrangement of the alignment keys. This effect may be achieved by manufacturing more precise alignment keys in Fabs in which semiconductor chips are manufactured than in Fabs in which package substrates are manufactured.

A first passivation layer 240 may extend along the upper surface of the first semiconductor chip 210. In one or more examples, the first passivation layer 240 may surround the side surfaces of the first chip pad 230.

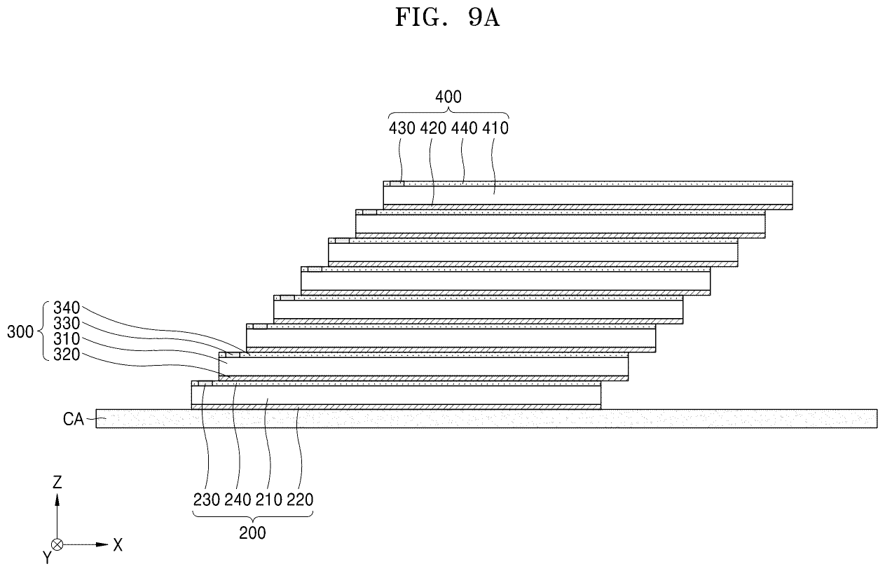

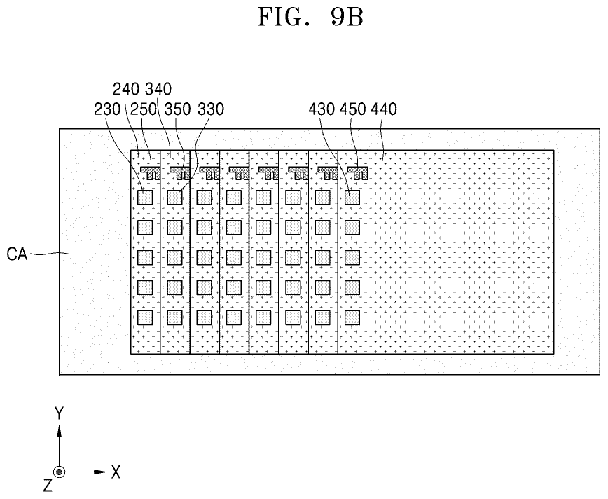

Referring to FIGS. 9A and 9B, a plurality of second semiconductor chip structures 300 and a third semiconductor chip structure 400 may be stacked on the first semiconductor chip structure 200 to form a stepped shape in a first horizontal direction (e.g., an X direction).

The plurality of second semiconductor chip structures 300 may each include a second semiconductor chip 310, a second chip pad 330, a second passivation layer 340, and a second alignment key 350. The third semiconductor chip structure 400 may include a third semiconductor chip 410, a third chip pad 430, a third passivation layer 440, and a third alignment key 450.

In a plan view, the plurality of second semiconductor chip structures 300 and the third semiconductor chip structure 400 may be stacked in an offset manner such that the first chip pad 230, the plurality of second chip pads 330, and the third chip pad 430 are exposed. During the process of stacking the second semiconductor chip structures 300 and the third semiconductor chip structure 400, the first alignment key 250, the second alignment key 350, the third alignment key 450, the second semiconductor chip 310, and the third semiconductor chip 410 may be aligned with each other, as described with reference to FIG. 3A. According to embodiments, the first alignment key 250, the second alignment key 350, the third alignment key 450, the second semiconductor chip 310, and the third semiconductor chip 410 may be aligned with each other during the process of stacking the second semiconductor chip structures 300 and the third semiconductor chip structure 400, as described with reference to FIGS. 3B, 4, 5A, 5B, 6A, 6B, and 6C.

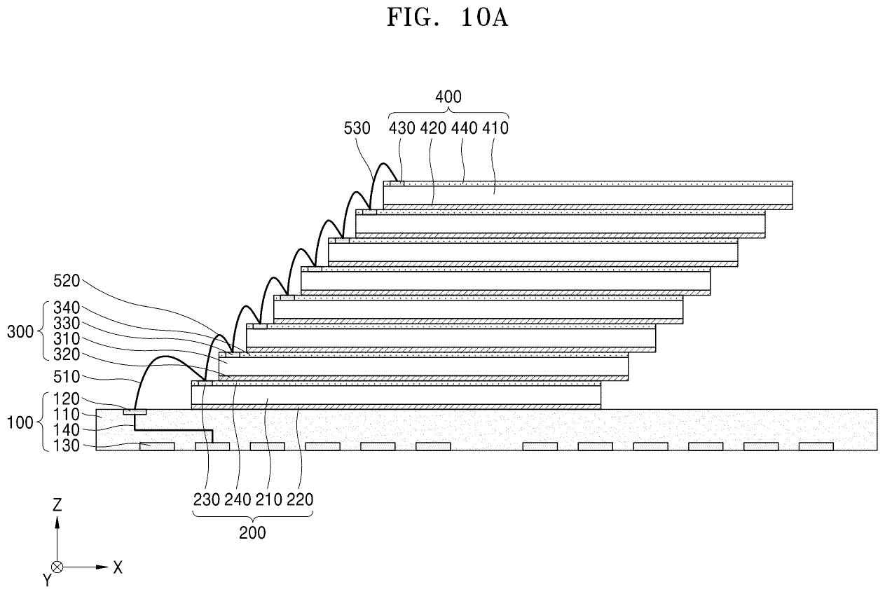

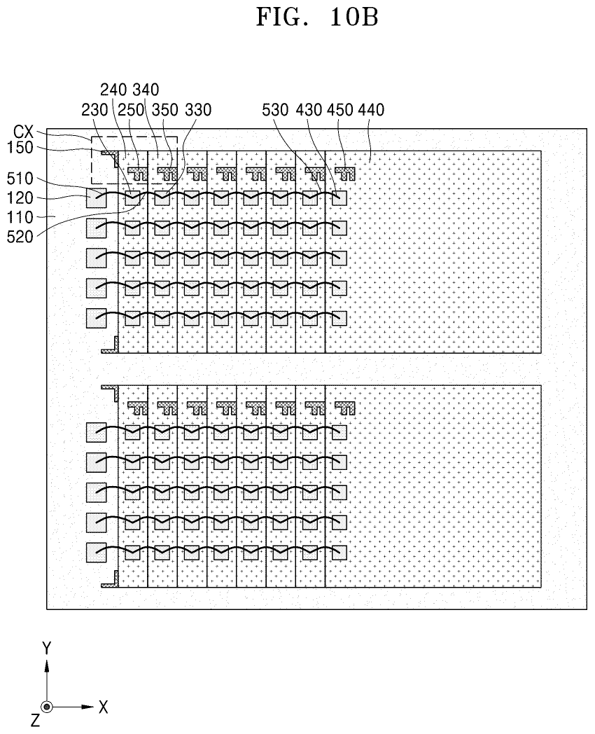

Referring to FIGS. 10A and 10B, after the carrier substrate CA is removed, the first semiconductor chip structure 200 may be mounted on the package substrate 100. In one or more examples, the plurality of second semiconductor chip structures 300 and the third semiconductor chip structure 400 may be stacked on the first semiconductor chip structure 200.

The package substrate 100 may include a substrate body 110, an upper pad 120, a lower pad 130, and an internal wiring line 140.

During the process of stacking the first semiconductor chip structure 200 on the package substrate 100, the substrate alignment key 150 and the first semiconductor chip 210 may be aligned with each other, as described with reference to FIG. 3A.

Subsequently, there may be attached a first wire 510 that forms a connection between the upper pad 120 and the first chip pad 230, second wires 520 that form connections between the first wire 510 and the lowermost second chip pad 330 and between the plurality of second chip pads 330, and a third wire 530 that forms a connection between the lowermost second chip pad 330 and the third chip pad 430.

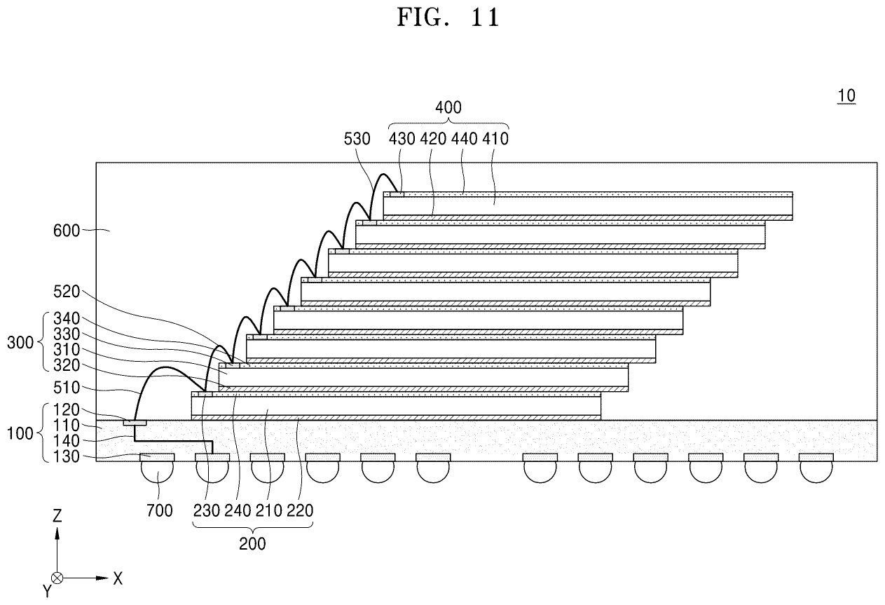

Referring to FIG. 11, subsequently, a molding layer 600 is formed on the package substrate 100 to seal the first semiconductor chip structure 200, the plurality of second semiconductor chip structures 300, the third semiconductor chip structure 400, and the first to third wires 510, 520, and 530. Then, an external connection terminal 700 may be formed on the lower pad 130 of the package substrate 100 and, consequently, the semiconductor package 10 may be completed.

While the present disclosure has been particularly shown and described with reference to embodiments thereof, it will be understood that various changes in form and details may be made therein without departing from the spirit and scope of the following claims.

What is claimed is:

1. A semiconductor package comprising:
a first semiconductor chip;
a second semiconductor chip stacked on the first semiconductor chip to form a stepped shape in a first direction;
a first alignment key on an active surface of the first semiconductor chip, the first alignment key having a first surface parallel to the first direction and a second surface parallel to a second direction perpendicular to the first direction; and
a second alignment key on an active surface of the second semiconductor chip, the second alignment key having a third surface parallel to the first direction and a fourth surface parallel to the second direction,
wherein a surface of the second semiconductor chip, which is parallel to the second direction, is aligned with the second surface of the first alignment key in the first direction, and
wherein the first surface of the first alignment key is aligned with the third surface of the second alignment key in the second direction.

2. The semiconductor package of claim 1, wherein the first alignment key comprises:
a first extension extending in the first direction;
a second extension extending in the second direction; and
a third extension spaced apart from the second extension toward the second semiconductor chip and extending in the second direction,
wherein a surface of the third extension comprises the second surface of the first alignment key.

3. The semiconductor package of claim 2, wherein the first alignment key does not overlap the second semiconductor chip in a third direction perpendicular to the first direction and the second direction.

4. The semiconductor package of claim 1, wherein the first alignment key comprises:
a first extension extending in the first direction;
a second extension extending in the second direction; and
a third extension spaced apart from the second extension toward the second semiconductor chip and extending in the second direction,
wherein a surface of the second extension comprises the second surface of the first alignment key.

5. The semiconductor package of claim 4, wherein the first alignment key partially overlaps at least a portion of the second semiconductor chip in a third direction perpendicular to the first direction and the second direction.

6. The semiconductor package of claim 1, wherein at least one of the first alignment key and the second alignment key has an L-shape.

7. The semiconductor package of claim 1, wherein the first alignment key comprises:
a first extension extending in the first direction;
a second extension extending in the second direction; and
a third extension spaced apart from the second extension toward the second semiconductor chip and extending from the first extension in a direction opposite to the second direction,
wherein a surface of the third extension comprises the second surface of the first alignment key.

8. The semiconductor package of claim 1, wherein the first alignment key comprises:
a first extension extending in the first direction;
a second extension extending in the second direction; and
a third extension spaced apart from the second extension toward the second semiconductor chip and extending from the first extension in a direction opposite to the second direction,
wherein a surface of the second extension comprises the second surface of the first alignment key.

9. The semiconductor package of claim 1, wherein the first alignment key comprises:
a first pattern having a U-shape, a widest surface of the first pattern facing a surface of the first semiconductor chip that is closest to the widest surface of the first pattern;
a second pattern having a U-shape, a widest surface of the second pattern facing in a direction opposite to the surface of the first semiconductor chip that is closest to the widest surface of the second pattern; and
a third pattern having a U-shape and spaced apart from the first pattern in the first direction, a widest surface of the third pattern facing the surface of the first semiconductor chip that is closest to the widest surface of the third pattern,
wherein a surface of the third pattern comprises the second surface of the first alignment key.

10. The semiconductor package of claim 1, wherein the first alignment key comprises:
a first pattern having a U-shape, a widest surface of the first pattern facing a surface of the first semiconductor chip that is closest to the widest surface of the first pattern;
a second pattern having a U-shape, a widest surface of the second pattern facing in a direction opposite to the surface of the first semiconductor chip that is closest to the widest surface of the first pattern; and
a third pattern having a U-shape and spaced apart from the first pattern in the first direction, a widest surface of the third pattern facing the surface of the first semiconductor chip that is closest to the widest surface of the first pattern,
wherein a side surface of the second pattern comprises the second surface of the first alignment key.

11. The semiconductor package of claim 1, wherein the first alignment key comprises:
a first pattern having a U-shape, a widest surface of the first pattern facing a surface of the first semiconductor chip that is closest to the widest surface of the first pattern;
a second pattern having a U-shape, a widest surface of the second pattern facing in a direction opposite to the surface of the first semiconductor chip that is closest to the widest surface of the first pattern; and
a third pattern having a U-shape and spaced apart from the first pattern in the first direction, a widest surface of the third pattern facing the surface of the first semiconductor chip that is closest to the widest surface of the first pattern,
wherein a surface of the first pattern comprises the second surface of the first alignment key.

12. A semiconductor package comprising:
a package substrate;
a first semiconductor chip structure comprising a first semiconductor chip mounted on the package substrate;
a second semiconductor chip structure comprising a second semiconductor chip stacked on the first semiconductor chip structure to form a stepped shape in a first direction; and
a substrate alignment key on a surface of the package substrate, the substrate alignment key having a first alignment surface parallel to the first direction and a second alignment surface parallel to a second direction perpendicular to the first direction,
wherein the first semiconductor chip structure comprises a first alignment key on an active surface of the first semiconductor chip, the first alignment key having a first surface parallel to the first direction and a second surface parallel to the second direction,
wherein the second semiconductor chip structure comprises a second alignment key on an active surface of the second semiconductor chip, the second alignment key having a third surface parallel to the first direction and a fourth surface parallel to the second direction,
wherein a surface of the first semiconductor chip, which is parallel to the second direction, is aligned with the second alignment surface of the substrate alignment key, and
wherein a surface of the first semiconductor chip, which is parallel to the first direction, is aligned with the first alignment surface of the substrate alignment key.

13. The semiconductor package of claim 12, wherein a surface of the second semiconductor chip, which is parallel to the second direction, is aligned with the second surface of the first alignment key, and
wherein the first surface of the first alignment key is aligned with the third surface of the second alignment key.

14. The semiconductor package of claim 12, wherein the first semiconductor chip structure further comprises a first passivation layer extending along a surface of the first semiconductor chip.

15. The semiconductor package of claim 14, wherein the first alignment key is buried in the first passivation layer.

16. The semiconductor package of claim 14, wherein the first alignment key is located on the first passivation layer.

17. The semiconductor package of claim 14, wherein the first alignment key is below the first passivation layer, and
the first passivation layer comprises a transparent or translucent material.

18. The semiconductor package of claim 12, further comprising a molding layer on the package substrate and configured to seal the first semiconductor chip structure, the second semiconductor chip structure, and the substrate alignment key.

19. A semiconductor package comprising:
a package substrate;
a plurality of semiconductor chip structures comprising semiconductor chips stacked on the package substrate and offset from each other in an first direction to form a stepped shape; and
a substrate alignment key on an active surface of the package substrate, the substrate alignment key having a first alignment surface parallel to the first direction and a second alignment surface parallel to a second direction perpendicular to the first direction,
wherein each of the plurality of semiconductor chip structures comprises:
an alignment key, and
a passivation layer extending along a surface of a respective semiconductor chip, the alignment key being buried in the passivation layer,
wherein a surface, parallel to the second direction, of a semiconductor chip of a semiconductor chip structure of the plurality of semiconductor chip structures closest to the package substrate is aligned with the second alignment surface of the substrate alignment key, and
a surface, parallel to the first direction, of the semiconductor chip structure of the plurality of semiconductor chip structures closest to the package substrate is aligned with the first alignment surface of the substrate alignment key.

20. The semiconductor package of claim 19, wherein the plurality of semiconductor chip structures comprise:
a first semiconductor chip and a second semiconductor chip, which are adjacent to each other in a third direction perpendicular to the first direction and the second direction;
a first alignment key on a surface of the first semiconductor chip; and
a second alignment key located on a surface of the second semiconductor chip,
wherein a surface of the second semiconductor chip, which is parallel to the second direction, is aligned with a surface of the first alignment key, which is parallel to the second direction, and
a surface of the first alignment key, which is parallel to the first direction, is aligned with a surface of the second alignment key, which is parallel to the first direction.
